(19) United States
(12) Patent Application Publication
(10) Pub. No.: US 2009/0008766 A1
(43) Pub. Date: Jan. 8, 2009

(54) High-Density Fine Line Structure And Method Of Manufacturing The Same

(76) Inventors: Chien-Wei Chang, Taoyuan (TW); Ting-Hao Lin, Taipei (TW)

Correspondence Address: LIN & ASSOCIATES INTELLECTUAL PROPERTY, INC., P.O. BOX 2339, SARATOGA, CA, 95070-0339, US

(21) Appl. No.: 11/772,812

(22) Filed: Jul. 2, 2007

(51) Int. Cl. H01L 23/48; H01L 21/58

(52) U.S. Cl. 257/691; 438/108; 257/E23.01; 257/E21.505

(57) ABSTRACT

A high-density fine line structure mainly includes two semiconductor devices formed on the same surface, without stacking to each other. One of the semiconductor devices is directly installed on a fine line circuit layer, and the other semiconductor device is installed on the fine line circuit layer within a dielectric layer cavity. In the method of the present invention, electroplating rather than the etching method is used for forming the fine line circuit layer, and a carrier and a metal barrier layer, which are needed during or at the end of the manufacturing process, are removed to increase the wiring density for realizing the object of high-density.

### BACKGROUND OF THE INVENTION

1. Field of the Invention

The present invention relates generally to a method of manufacturing a package structure, and in particular to a high-density fine line structure and method of manufacturing the same.

2. The Prior Arts

One of the important challenges in the IC industry is how to keep under a proper cost for assembling various types of functions inside a limited package form done effectively, so that chips performing different functions are to reach optimal performance. However, in the applications as used in the digital, analog, memory, and wireless communications fields, etc, different electrical circuits having different functionalities can produce different performance requirements and results corresponding to under the production technology scaling. Therefore, a single chip having many integrated functions may not provide the most optimal solution. As the SOC, SiP, PiP (Package-in-Package), PoP (Package-on-Package), and stack CSP technique have rapidly advanced, it can be predicted that the most capable system chip is a packaged system which can make the most of the space allowance to integrate various chips having different functions under the various different technologies and different voltage operation environments.

In detail, the system-in-package (SIP) is a package in which chips of various IC types are assembled. A new technique which is developed from the SIP is to be able to stack many chips inside a package module, and to be able to provide or integrate more functions or higher density by utilizing the third dimensional space. In packaging structures, the stack CSP is firstly launched to the public, of which the corresponding products are memory combo, and is able to stack six layers of memory chips in a BGA package. Herein, apart from the conventional wire bonding, the solder bumps or the flip-chip technique can also be used, while the interposers can be added to assist stacking, or perhaps the heat extraction can also be gradually applied.

For example, a package of the stack chips should include the dies as the building blocks which are in separated-form each other, but are connected with each other by conducting wires, and may include the stack of one or more memory chips, an analog chip stacked on another SOC or digital chip, and also another separate RF chip disposed on a multi-layer interconnected substrate, where these chips have different control and I/O (input/output) paths. Moreover, if there is a memory in the stacked chip, the control software can write into the non-volatile memory (NVM).

However, because the conventional fine line technique is unable to achieve any major breakthrough in technology, the manufacturing process for fabricating the more complicated package structure as described above cannot yield greater further overall package volume reductions, for meeting the growing thinner and lighter requirements of the electronic devices.

In the conventional manufacturing of the 50 μm fine pitch line circuit on the build up material such as the glass-fiber-reinforced resin material, the method includes: using a 1.5-5.0 μm thin copper as the conductive layer for the pattern plating, the flash etching is performed to etch the thin copper layer with thickness of 1.5-5.0 μm. Because a rough surface of the thin copper layer is required to be combined with the glass-fiber-reinforced resin material, the rough surface structure of the thin copper layer is therefore required in the corresponding method. According to the structure, the etching operation as required is to lead to increased etching depth for processing, thereby resulting in the damage to the wire width after plating. Due to the thickness of the thin copper layer, the etching amount may not be reduced further, and therefore, high-density board having thinner fine pitch lower than 50 μm can not be manufactured.

During plating of the nickel on the fine line circuit layer of the printed circuit board, the electrical current is transmitted into the board, especially for the fine line circuit layer required to be electroplated, it is necessary that the electrical current may be transmitted by the conductor trace lines which are connected with the fine line circuit layer. Although the fine line circuit layer can be fully covered using the plated nickel layer by this method, the conductor trace lines are still retained in the printed circuit board after the plating, and thereby to occupy the limited wiring density. In order to decrease the wiring density, because the width of the conductor trace line then becomes relatively narrowed, the thickness of the plated nickel layer may not be uniform; therefore, the decrease of the width of the conductor trace line may not be suitable for use for increasing the wiring density.

In order to improve electrical performance and reducing interference, and at the same time, to increase the wiring density, the printed circuit board currently are designed without the conductor trace lines, and the adhesion of the wire bonding region may be optimized by nickel plating the nickel, rather than by using the chemical nickel plating (or the chemical gold plating) whose reliability is not as good. Therefore, the wire bonding region made without conductor trace lines but using nickel plating method are typically manufactured by the GPP operation.

However, before performing the GPP operation, because the plated nickel layer is formed before the solder mask (SM), the area of the plated nickel layer occupied under the SM is relatively large. Because the adhesion between the SM and the plated nickel layer is poor, the relatively high requirement for reliability and thermal stability today is unable to be met by the conventional manufacturing methods.

Otherwise, in the manufacturing method as in the non-plating line (NPL) method, besides having a complex set of procedures, a specialized machine is required for use for plating the thin copper layer, and the etching parameters for the etching are difficult for control after plating the thin copper; as a result, micro short are often resulted, or the micro short occurring during reliability testing are produced resulting in unmanageable situations.

No matter whichever type of NPL manufacturing method is used, the fine line layer is to be defined by the un-etched metal layer, and sometimes to rely on the selective etching of the metal layer. But, according to conventional method, the etching cannot be controlled accurately; therefore, the manufacturing of the fine line circuit cannot rely reliably upon etching, otherwise the fine pitch line circuit faces tremendous development barrier.

### SUMMARY OF THE INVENTION

A primary objective of the present invention is to provide a high-density fine line structure and method of manufacturing the same, which comprises two semiconductor devices formed on the same surface, without stacking to each other, to reduce the thickness of the overall packaging structure. Without using etching as the method for forming the circuit, only the patterned photoresist layer is used to define the location of the fine line layer, and the plating method is used to form the fine line layer (the plating electrical current is transmitted by a removable carrier or a metal barrier layer hereon.), and to form the fine line circuit for realizing the thinning effect. Later, the carrier and the metal barrier layer may be removed during or at the end of the manufacturing process to increase the wiring density for realizing the higher-density objective. Meanwhile, the higher-cost semi-additive process (SAP) technique is also not used in the present invention.

Based upon the above objective, the solution of the present invention is to provide a high-density fine line structure, mainly includes a first semiconductor device directly installed on the fine line circuit layer and a second semiconductor installed on the fine line circuit layer within a dielectric layer cavity. In the method of the present invention, electroplating rather than the etching method is used for forming the fine line circuit layer, and a carrier and a metal barrier layer, which are needed during or at the end of the manufacturing process, are removed to increase the wiring density for realizing the object of high-density.

### BRIEF DESCRIPTION OF THE DRAWINGS

The present invention will be apparent to those skilled in the art by reading the following detailed description of a preferred embodiment thereof, with reference to the attached drawings, in which:

FIGS. 1A-1D are cross-sectional views showing a fine line circuit layer in accordance with the present invention; and

FIGS. 2A-2E are cross-sectional views showing a 3D packaging structure in accordance with the present invention.

### DETAILED DESCRIPTION OF THE PREFERRED EMBODIMENT

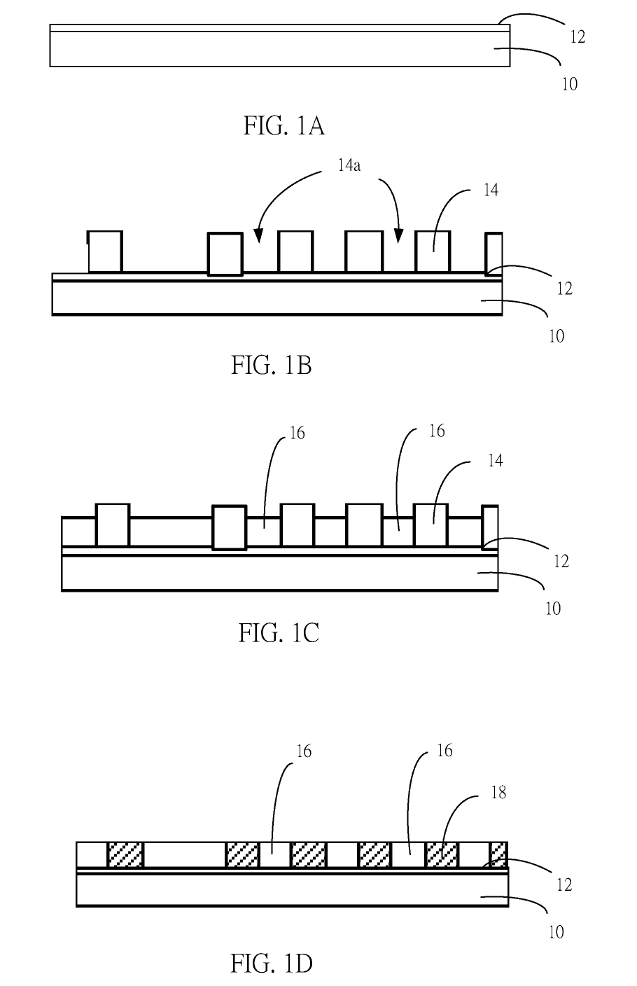

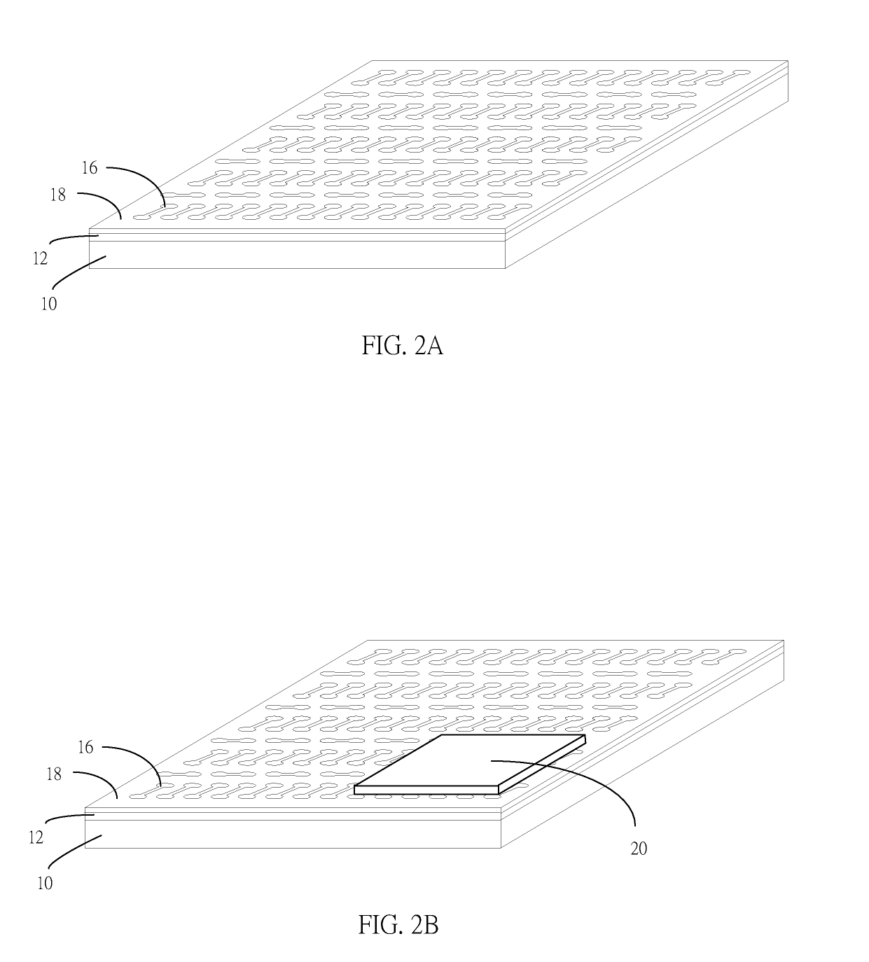

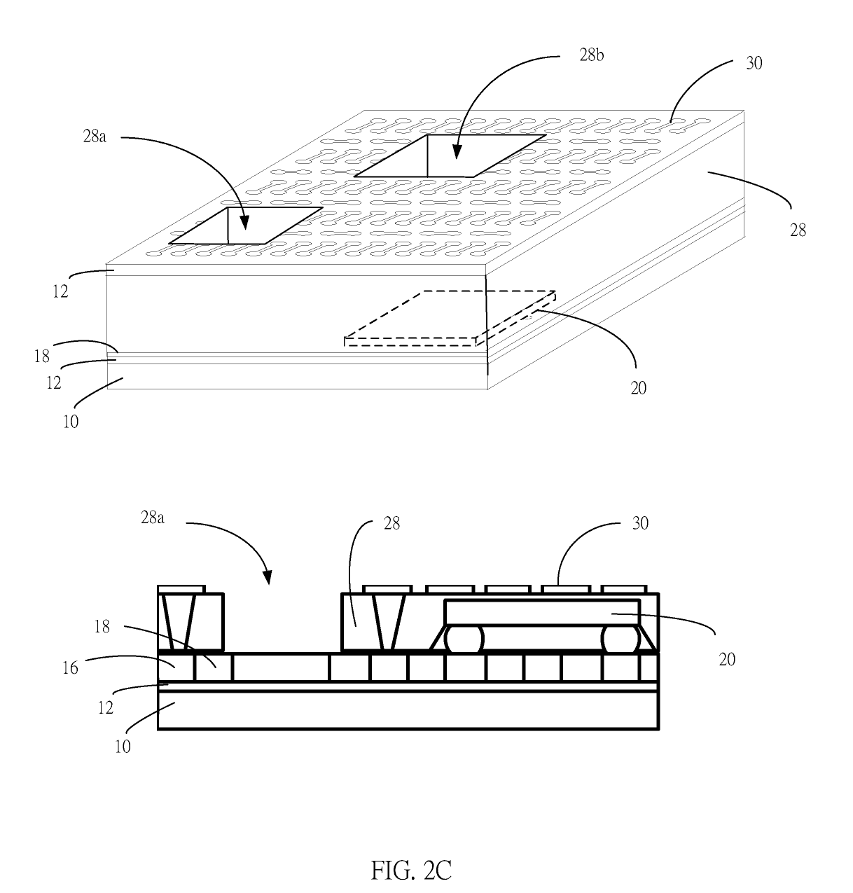

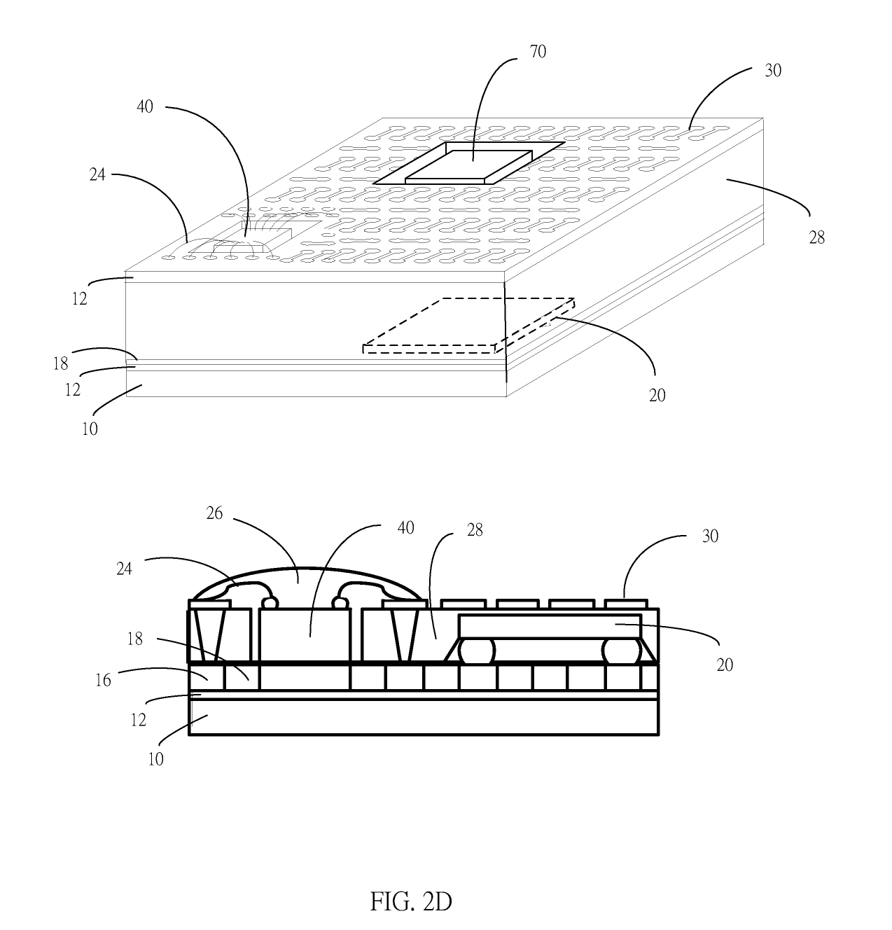

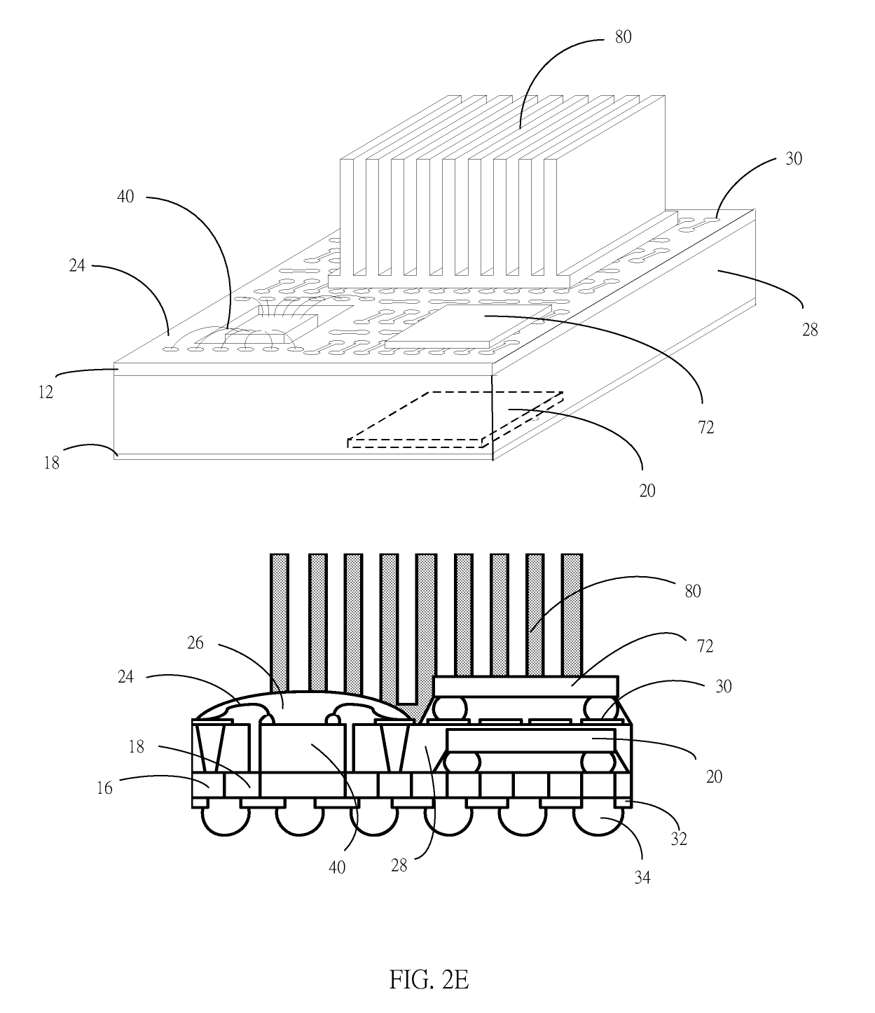

With reference to the drawings and in particular to FIGS. 1A-1D, a manufacturing method of a high-density fine line structure provided in accordance with the present invention is shown, in which the part for forming the circuit without etching is shown in FIGS. 1A-1D, and the completed 3D packaging structure is presented in FIGS. 2A-2E.

Simply speaking, as shown in FIG. 2D, the high-density fine line structure and the method of manufacturing the same provided in the present invention mainly includes: a first semiconductor device 20 and a second semiconductor device 40 formed on the same surface, without stacking to each other, to reduce the thickness of the overall packaging structure. As shown in FIGS. 1A-1D, without using etching as the method for forming the circuit, only the patterned photoresist layer 14 is used to define the location of the fine line layer 16, and the plating method is used to form the fine line layer 16 (the plating electrical current is transmitted by a removable carrier 10 or a metal barrier layer 12 hereon.), and to form the fine line circuit for realizing the thinning effect. Later, the carrier 10 and the metal barrier layer 12 may be removed during or at the end of the manufacturing process as shown in FIG. 2E to increase the wiring density for realizing the higher-density objective. Below, the manufacturing method as shown in FIGS. 2A-2E is described at first, and the manufacturing method of the fine line circuit layer 16 as shown in FIGS. 1A-1D is described later. The structure as shown in FIG. 2A is manufactured by the steps showed in FIGS. 1A-1D.

As shown in FIG. 2B, a first semiconductor device 20 is installed on the fine line circuit layer 16. Then, as shown in FIG. 2C, a dielectric layer 28 is formed above the fine line circuit layer 16 which is not covered by the first semiconductor device 20, and above the first semiconductor device 20. Thus, a predetermined position of the dielectric layer 28 is etched to expose the fine line circuit layer 16, and form a first dielectric layer cavity 28a at least. As shown in FIG. 2D, a second semiconductor device 40 is installed on the fine line circuit layer 16 within the first dielectric layer cavity 28a. Therefore, the first semiconductor device 20 and the second semiconductor device 40 are formed on the same surface, without stacking to each other.

When the first semiconductor device 20 is installed on the fine line circuit layer 16, the second semiconductor device 40 may be also installed by using the wire bonding to form the first semiconductor device 20 and the second semiconductor device 40 on the same surface. However, the thickness of the overall structure may be increased as well. The reason is that if the conductor trace line 24 for the second semiconductor device 40 (as shown in FIG. 2D) is not electrically connected with the outer circuit layer 30 but with the fine line circuit layer 16, the thickness of the second semiconductor device 40 may cause the great high difference, and the adhesive 26 with thicker thickness is required to cover the second semiconductor device 40 and the conductor trace lines 24, which causes the overall package thickness increased. Herein, the outer circuit layer 30 is formed on the dielectric layer 28, where the first dielectric layer cavity 28a is not formed.

If the second semiconductor device 40 is not installed as FIG. 2C, in which the first dielectric layer cavity 28a is not etched at first, the second semiconductor device 40 is adhered on the dielectric layer 28, and the second semiconductor device 40 is electrically connected to with the outer circuit layer 30 by the conductor trace lines 24, the first semiconductor device 20 and the second semiconductor device 40 may be stacked, which causes the overall thickness increased. Therefore, forming the first dielectric layer cavity 28a is one of the methods to form the first semiconductor device 20 and the second semiconductor device 40 on the same surface.

At last, as shown in FIG. 2E, the carrier 10 and the metal barrier layer 12 may be removed to expose the fine line circuit layer 16. Parts of the fine line circuit layer 16 can be used as the tin ball pads, for filling in the tin ball 34, for ease to install on the other circuit boards.

Besides, as shown in FIG. 2C, when the dielectric layer 28 is etched, a second dielectric layer cavity 28b may be formed simultaneously. As shown in FIG. 2D, a third semiconductor device 70 is installed on the fine line circuit layer 16 within the second dielectric layer cavity 28b by using the flip chip.

Because the second semiconductor device 40 and the third semiconductor device 70 are respectively installed in the first dielectric layer cavity 28a and the second dielectric layer cavity 28b, the heat radiation piece 80 may be disposed on the second semiconductor device 40 or the third semiconductor device 70, to improve the reliability of the system. However, if the second semiconductor device 40 is installed by the wire bonding, the heat radiation piece 80 is improper to be disposed on the second semiconductor device 40.

Although the present invention is mainly to provide a packaging structure with two semiconductor devices formed on the same surface, it does not mean that no semiconductor devices can be stacked in the present invention. Thus, as shown in FIG. 2E, the pad which is filled with the tin ball can be electrically connected with a fourth semiconductor device 72.

Specially, in this structure, the fine line circuit layer 16 may be a plurality of layers, and at the furthest outer layer of the outer fine line circuit layer 30, besides the installation of the fourth semiconductor device 72 as shown in FIG. 2E, the passive device 60 may also be installed.

To further reduce the thickness, the fine line circuit layer 16 may be also formed as shown in FIG. 1D. In detail, the metal barrier layer 12 is first formed on the carrier 10, in particular as shown in FIG. 1A. For forming the fine line circuit layer 16 as shown in FIG. 1B, the patterned photoresist layer 14 is formed above the metal barrier layer 12 (whose photoresist opening 14a is for forming the circuit). And as shown in FIG. 1C, plating current is transmitted through the metal barrier layer 12, and then the fine line circuit layer 16 may be formed on the metal barrier layer 12 in the photoresist opening 14a. Thus, the patterned photoresist layer 14 is removed. After the formation of the fine line circuit layer 16, the insulated layer 18 may be filled adjacent to the fine line circuit layer 16 on the metal barrier layer 12, as show in FIG. 1D.

Before filling in the insulated layer 18, in order to improve the reliability of the adhesive between the fine line circuit layer 16 and the filled insulated layer 18, the surface of the fine line circuit 16 may be processed first to increase the surface area and the degree of roughness of the fine line circuit layer 16. The surface processing can be performed by roughening the surface of the fine line circuit 16 or by forming a plurality of copper micro-bumps (or nodules) on the surface. Whatever the method is used, the purpose is that the fine line circuit layer 16 can remain firmly adhered to the insulated layer 18 and other package components due to the increased contact surface area, after removing the carrier 10 and the metal barrier layer 12 which were used to support the fine line circuit layer 16.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A manufacturing method of a high-density fine line structure, comprising:
forming a metal barrier layer on a carrier;
forming a patterned photoresist layer on the metal barrier layer, and the patterned photoresist layer having a photoresist opening;
transmitting a plating current through the metal barrier layer, and forming a fine line circuit layer on the metal barrier layer in the photoresist opening;
removing the patterned photoresist layer;
filling in an insulated layer on the metal barrier layer and at the side of the fine line circuit layer;
installing a first semiconductor device above the fine line circuit layer;
forming a dielectric layer above the fine line circuit layer which is not covered by the first semiconductor device, and above the first semiconductor device;
etching the dielectric layer to expose the fine line circuit layer and form a first dielectric layer cavity;
installing a second semiconductor device on the fine line circuit layer within the first dielectric layer cavity; and
removing the carrier, the metal barrier layer, and exposing the fine line circuit layer, parts of the fine line circuit layer are able to be a tin ball pad, as is used for filling in a tin ball,
wherein, the first semiconductor device and the second semiconductor device are formed on the same surface.

2. The method as claimed in claim 1, wherein during etching the dielectric layer, a second dielectric layer cavity is formed simultaneity, and a third semiconductor device is installed on the fine line circuit layer within the second dielectric layer cavity.

3. The method as claimed in claim 1, further comprising: forming an outer circuit layer on the dielectric layer, where the first dielectric layer cavity is not formed.

4. The method as claimed in claim 3, further comprising: selectively forming a solder mask on the outer circuit layer, and the other surface which is not covered by the solder mask is to be made into a pad.

5. The method as claimed in claim 4, wherein the pad, which is filled with the tin balls, is electrically connected with a fourth semiconductor device.

6. The method as claimed in claim 2, wherein the installation of the first semiconductor device, the second semiconductor device, and the third semiconductor device are processed by using wire bonding or flip chip.

7. The method as claimed in claim 3, wherein the installation of the fourth semiconductor device is processed by using wire bonding or flip chip.

8. The method as claimed in claim 2, further comprising: a heat radiation piece is disposed on the second semiconductor device or the third semiconductor device.

9. A high-density fine line structure, comprising:
a fine line circuit layer;
an insulating layer, formed on the same surface as the fine line circuit layer; and
a dielectric layer, formed on the fine line circuit layer and the insulated layer, and having a first dielectric layer cavity;
a first semiconductor device, installed on the fine line circuit layer directly; and
a second semiconductor device, installed on the fine line circuit layer within the first dielectric layer cavity, and on the same surface as the first semiconductor device,
wherein, the fine line circuit layer, which is exposed, can be a tin ball pad for filling in a tin ball.

10. The structure as claimed in claim 9, wherein, the dielectric layer has a second dielectric layer cavity, and a third semiconductor device is installed on the fine line circuit layer within the second dielectric layer cavity.

11. The structure as claimed in claim 9, further comprising: an outer circuit layer, formed on the dielectric layer, where the first dielectric layer cavity is not formed.

12. The structure as claimed in claim 11, further comprising: a solder mask, selectively forming on the outer circuit layer, and the other surface of the outer circuit layer which is not covered by the solder mask is to be made into a pad.

13. The structure as claimed in claim 12, wherein, the pad, which is filled with the tin ball, is electrically connected with a fourth semiconductor device.

14. The structure as claimed in claim 10, wherein the installation of the first semiconductor device, the second semiconductor device, and the third semiconductor device are processed by using wire bonding or flip chip.

15. The structure as claimed in claim 13, wherein the installation of the fourth semiconductor device is processed by using wire bonding or flip chip.

16. The structure as claimed in claim 10, further comprising: a heat radiation piece is disposed on the second semiconductor device or the third semiconductor device.
